(19) United States
(12) Patent Application Publication
(10) Pub. No.: US 2022/0380572 A1
(43) Pub. Date: Dec. 1, 2022

(54) Magnetic Polymer Composition

(71) Applicant: Ticona LLC, Florence, KY (US)

(72) Inventor: Young Shin Kim, Cincinnati, OH (US)

(21) Appl. No.: 17/826,233

(22) Filed: May 27, 2022

Related U.S. Application Data
(60) Provisional application No. 63/247,851, filed on Sep. 24, 2021.
(60) Provisional application No. 63/195,285, filed on Jun. 1, 2021.

(51) Int. Cl. C08K 3/38; C08K 3/04; G01R 33/02

(52) U.S. Cl. CPC C08K 3/38; C08K 3/04; G01R 33/02; C08K 2201/01; C08K 2201/005

(57) ABSTRACT

A polymer composition comprising from about 20 vol. % to about 60 vol. % of a polymer matrix that includes a liquid crystalline polymer and from about 20 vol. % to about 60 vol. % of magnetic particles is provided. The ratio of the volume of the polymer matrix to the volume of the magnetic particles is from about 0.6 to about 1.5.

### RELATED APPLICATIONS

The present application is based upon and claims priority to U.S. Provisional Patent Application Ser. No. 63/195,285, having a filing date of Jun. 1, 2021, and U.S. Provisional Patent Application Ser. No. 63/247,851, having a filing date of Sep. 24, 2021, which are incorporated herein by reference.

### BACKGROUND OF THE INVENTION

Magnetic components (e.g., sensors) are often employed in electronic devices. Magnetic sensors, for instance, can detect a magnetic field along a particular axis or a surface (of the magnetic field sensor), while not detecting (or effectively ignoring) magnetic fields along other axes or surfaces. Unfortunately, the metals used to form most magnetic components are often costly and difficult to incorporate into smaller portable electronic devices due to their large size. Likewise, attempts at using polymer compositions with magnetic properties to enable the manufacture of smaller and more precise components has been rendered difficult based on the inability of conventional polymer compositions to exhibit both magnetic properties and a high degree of heat resistance. As such, a need exists for an improved magnetic polymer composition for use in magnetic components.

### SUMMARY OF THE INVENTION

In accordance with one embodiment of the present invention, a polymer composition is disclosed that comprises from about 20 vol. % to about 60 vol. % of a polymer matrix that includes a liquid crystalline polymer and from about 20 vol. % to about 60 vol. % of magnetic particles. The ratio of the volume of the polymer matrix to the volume of the magnetic particles is from about 0.6 to about 1.5.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is a perspective front view of one embodiment of an electronic device that may contain a magnetic sensor;

FIG. 2 is a diagram of illustrative circuitry and components for an electronic device having magnetic sensors;

FIG. 3 is a perspective view of an illustrative housing to which magnetic sensors are attached in various orientations;

FIG. 4 is a perspective view of an electronic component within a device housing to which magnetic sensors are attached in various orientations;

FIG. 5 is a perspective view of an illustrative set of magnetic sensors that are attached to a cowling structure that covers an electronic component;

FIG. 6 is a perspective view of an illustrative set of magnetic sensors that are attached to a cowling structure having folded portions in multiple orientations that cover an electronic component;

FIG. 7 is a top view of an illustrative unidirectional magnetic sensor that may employ the polymer composition of the present invention;

FIG. 8 is a cross-sectional side view of an illustrative unidirectional magnetic sensor that may employ the polymer composition of the present invention;

FIG. 9 is a perspective view of an illustrative unidirectional magnetic sensor having a stepped edge for low-profile coupling to a flexible circuit;

FIG. 10 is a cross-sectional side view of an illustrative magnetic sensor having a reference sensor element that may contain the polymer composition of the present invention;

FIG. 11 is a top view of an illustrative bidirectional magnetic sensor that may contain the polymer composition of the present invention; and

FIG. 12 is a top view of an illustrative bidirectional magnetic sensor with a shared reference sensor element that may contain the polymer composition of the present invention.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a magnetic polymer composition for use in an electronic device. More particularly, the magnetic polymer composition contains a polymer matrix that includes a liquid crystalline polymer and magnetic particles distributed within the polymer matrix. The magnetic particles may constitute from about 50 wt. % to about 99 wt. %, in some embodiments from about 50 wt. % to about 95 wt. %, in some embodiments from about 60 wt. % to about 90 wt. %, and in some embodiments, from about 70 wt. % to about 88 wt. % of the polymer composition, as well as from about 20 vol. % to about 60 vol. %, in some embodiments from about 30 vol. % to about 55 vol. %, and in some embodiments, from about 35 vol. % to about 55 vol. % of the polymer composition. The polymer matrix may likewise constitute from about 8 wt. % to about 50 wt. %, in some embodiments from about 10 wt. % to about 40 wt. %, and in some embodiments, from about 12 wt. % to about 30 wt. % of the polymer composition, as well as from about 20 vol. % to about 60 vol. %, in some embodiments from about 30 vol. % to about 55 vol. %, and in some embodiments, from about 35 vol. % to about 55 vol. % of the polymer composition. Typically, the volume of the polymer matrix and the magnetic particles are relatively similar such that the ratio of the volume of the polymer matrix to the volume of the magnetic particles is from about 0.6 to about 1.5, in some embodiments from about 0.8 to about 1.4, and in some embodiments, from about 0.9 to about 1.3.

Through careful control over the specific nature and concentration of the components employed in the composition, the present inventors have discovered that the resulting composition can exhibit a unique combination of magnetic properties and heat resistance. For example, the polymer composition may exhibit a relative high remanence value (Br), which is characteristic of the overall strength of the magnetic field created by the particles. The remanence value may, for instance, range 300 to about 2,000 mT, in some embodiments from about 350 to about 1,500 mT, and in some embodiments, from about 400 to about 1,000 mT, such as determined at a temperature of 23° C. in accordance with JIS C 2501:2019 (generally equivalent to ASTM A977/A977M-07 (2020)). The maximum energy product (BHₘₐₓ), which is the density of magnetic energy characterized by the product of the maximum value of magnetic flux density (B) and magnetic field strength (H), may also be high, such as from about 15 to about 200 kJ/m³, in some embodiments from about 20 to about 150 kJ/m³, in some embodiments from about 25 to about 100 kJ/m³, and in some embodiments, from about 30 to about 60 kJ/m³, such as determined at a temperature of 23° C. in accordance with JIS C 2501:2019 (generally equivalent to ASTM A977/A977M-07 (2020)). In addition to exhibiting a strong degree of magnetic properties, the particles are also capable of maintaining such properties under a variety of conditions. For example, the particles may exhibit a high degree of intrinsic coercivity (H_{ci}), which is a property characteristic of the ability of the particles to resist becoming demagnetized. For example, the intrinsic coercivity may range from about 400 to about 3,000 kA/m, in some embodiments from about 700 to about 2,500 kA/m, and in some embodiments, from about 900 to about 1,500 kA/m, such as determined at a temperature of 23° C. in accordance with JIS C 2501:2019 (generally equivalent to ASTM A977/A977M-07 (2020)).

The Curie temperature (Tc), which is the temperature at which the material loses its magnetism, may also be high, such as from about 200° C. to about 400° C., in some embodiments from about 250° C. to about 350° C., and in some embodiments, from about 280° C. to about 320° C., such as determined by thermogravimetric analysis in accordance with ASTM E1582-17. Further, the polymer composition may also exhibit a high melting temperature (“Tm”), such as about 280° C. or more, in some embodiments about 290° C. or more, in some embodiments from about 300° C. to about 400° C., and in some embodiments, from about 320° C. to about 360° C., as determined by differential scanning calorimetry (“DSC”) in accordance with ISO Test No. 11357-2:2020. In addition to exhibiting a high melting temperature, the composition may also be heat resistant. For example, the composition may exhibit a deflection temperature under load (DTUL) of about 200° C. or more, in some embodiments about 210° C. or more, and in some embodiments, from about 220° C. to about 300° C., as measured according to ISO Test No. 75-2:2013 at a specified load of 1.8 MPa.

Despite exhibiting such a good magnetic properties and heat resistance, the polymer composition may nevertheless still exhibit excellent mechanical properties. For example, the composition may exhibit an Izod unnotched impact strength of about 4 kJ/m² or more, in some embodiments from about 5 to about 60 kJ/m², and in some embodiments, from about 8 to about 50 kJ/m², measured at 23° C. according to ASTM D256-10 (2018). The composition may also exhibit a tensile strength of from about 20 to about 500 MPa, in some embodiments from about 30 to about 300 MPa, and in some embodiments, from about 40 to about 150 MPa; tensile break strain of about 0.5% or more, in some embodiments from about 0.8% to about 15%, and in some embodiments, from about 1% to about 10%; and/or tensile modulus of from about 5,000 MPa to about 30,000 MPa, in some embodiments from about 7,000 MPa to about 25,000 MPa, and in some embodiments, from about 9,000 MPa to about 20,000 MPa. The tensile properties may be determined in accordance with ISO Test No. 527-2:2019 at 23° C. The composition may also exhibit a flexural strength of from about 40 to about 500 MPa, in some embodiments from about 50 to about 300 MPa, and in some embodiments, from about 70 to about 200 MPa; flexural break strain of about 0.5% or more, in some embodiments from about 0.8% to about 15%, and in some embodiments, from about 1% to about 10%; and/or flexural modulus of about 7,000 MPa or more, in some embodiments from about 8,000 MPa or more, in some embodiments, from about 9,000 MPa to about 30,000 MPa, and in some embodiments, from about 10,000 MPa to about 25,000 MPa. The flexural properties may be determined in accordance with ISO Test No. 178:2019 at 23° C.

Various embodiments of the present invention will now be described in more detail.

### I. Polymer Composition

A. Polymer Matrix

The polymer matrix typically contains one or more liquid crystalline polymers, which are generally classified as “thermotropic” to the extent that they can possess a rod-like structure and exhibit a crystalline behavior in their molten state (e.g., thermotropic nematic state). The polymers have a relatively high melting temperature, such as about 280° C. or more, in some embodiments about 290° C. or more, in some embodiments from about 300° C. to about 400° C., and in some embodiments, from about 320° C. to about 360° C., as determined by differential scanning calorimetry in accordance with ISO Test No. 11357-2:2020. Such polymers may be formed from one or more types of repeating units as is known in the art. A liquid crystalline polymer may, for example, contain one or more aromatic ester repeating units generally represented by the following Formula (I):

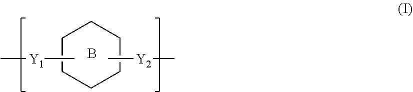

wherein,

ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and

Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula I are C(O)), aromatic hydroxycarboxylic repeating units (Y₁ is O and Y₂ is C(O) in Formula I), as well as various combinations thereof.

Aromatic hydroxycarboxylic repeating units, for instance, may be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). To help achieve the desired properties, the repeating units derived from hydroxycarboxylic acids (e.g., HBA and/or HNA) typically constitute about 20 mol. % or more, in some embodiments about 25 mol. % or more, in some embodiments about 30 mol. % or more, in some embodiments about 32 mol. % or more, in some embodiments from about 35 mol. % to about 90 mol. %, and in some embodiments, from about 40 mol. % to about 80 mol. % of the polymer.

Aromatic dicarboxylic repeating units may also be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) may each optionally constitute from about 1 mol. % to about 45 mol. %, in some embodiments from about 5 mol. % to about 40 mol. %, and in some embodiments, from about 10 mol. % to about 35% of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) may each optionally constitute from about 1 mol. % to about 45 mol. %, in some embodiments from about 2 mol. % to about 40 mol. %, and in some embodiments, from about 5 mol. % to about 35 mol. % of the polymer.

Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) may optionally constitute from about 0.1 mol. % to about 15 mol. %, in some embodiments from about 0.5 mol. % to about 10 mol. %, and in some embodiments, from about 1 mol. % to about 6 mol. % of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

In certain embodiments, the liquid crystalline polymer may be a “low naphthenic” polymer to the extent that it contains a relatively low content of repeating units derived from naphthenic hydroxycarboxylic acids and naphthenic dicarboxylic acids, such as NDA, HNA, or combinations thereof. That is, the total amount of repeating units derived from naphthenic hydroxycarboxylic and/or dicarboxylic acids (e.g., NDA, HNA, or a combination of HNA and NDA) is typically about 15 mol. % or less, in some embodiments about 12 mol. % or less, in some embodiments about 10 mol. % or less, and in some embodiments, from about 1 mol. % to about 6 mol. % of the polymer. In one embodiment, for instance, the repeating units derived from HNA may constitute from about 0.5 mol. % to about 15 mol. %, in some embodiments from about 1 mol. % to about 10 mol. %, and in some embodiments, from about 2 mol. % to about 8 mol. % of the polymer. The liquid crystalline polymer may also contain various other monomers. For example, the polymer may contain repeating units derived from HBA in an amount of from about 40 mol. % to about 80 mol. %, and in some embodiments from about 45 mol. % to about 75 mol. %, and in some embodiments, from about 50 mol. % to about 70 mol. %. When employed, the molar ratio of HBA to HNA may be selectively controlled within a specific range to help achieve the desired properties, such as from about 0.5 to about 20, in some embodiments from about 5 to about 20, in some embodiments from about 8 to about 18, and in some embodiments, from about 10 to about 15. Although not required in all instances, it is often desired that a substantial portion of the polymer matrix is formed from such low naphthenic polymers. For example, low naphthenic polymers such as described herein typically constitute 50 wt. % or more, in some embodiments about 65 wt. % or more, in some embodiments from about 70 wt. % to 100 wt. %, and in some embodiments, from about 80 wt. % to 100% of the polymer matrix (e.g., 100 wt. %).

If desired, the liquid crystalline polymer may also be a “high naphthenic” polymer to the extent that it contains a relatively high content of repeating units derived from naphthenic hydroxycarboxylic acids and naphthenic dicarboxylic acids, such as NDA, HNA, or combinations thereof. That is, the total amount of repeating units derived from naphthenic hydroxycarboxylic and/or dicarboxylic acids (e.g., NDA, HNA, or a combination of HNA and NDA) is greater than about 15 mol. %, in some embodiments about 18 mol. % or more, in some embodiments about 30 mol. % or more, in some embodiments about 40 mol. % or more, in some embodiments about 45 mol. % or more, in some embodiments 50 mol. % or more, in some embodiments about 55 mol. % or more, and in some embodiments, from about 55 mol. % to about 95 mol. % of the polymer. Without intending to be limited by theory, it is believed that such “high naphthenic” polymers are capable of reducing the tendency of the polymer composition to absorb water, which can aid in processability and the enhancement of physical properties. Namely, such high naphthenic polymers typically have a water adsorption of about 0.015% or less, in some embodiments about 0.01% or less, and in some embodiments, from about 0.0001% to about 0.008% after being immersed in water for 24 hours in accordance with ISO 62-1:2008. The high naphthenic polymers may also have a moisture adsorption of about 0.01% or less, in some embodiments about 0.008% or less, and in some embodiments, from about 0.0001% to about 0.006% after being exposed to a humid atmosphere (50% relative humidity) at a temperature of 23° C. in accordance with ISO 62-4:2008. In one embodiment, for instance, the repeating units derived from NDA may constitute from about 16 mol. % to about 50 mol. %, in some embodiments from about 16 mol. % to about 40 mol. %, in some embodiments from about 17 mol. % to about 35 mol. %, and in some embodiments, from about 18 mol. % to about 30 mol. % of the polymer. In such embodiments, the liquid crystalline polymer may also contain various other monomers, such as aromatic hydroxycarboxylic acid(s) (e.g., HBA) in an amount of from about 20 mol. % to about 60 mol. %, and in some embodiments, from about 30 mol. % to about 50 mol. %; aromatic dicarboxylic acid(s) (e.g., IA and/or TA) in an amount of from about 2 mol. % to about 30 mol. %, and in some embodiments, from about 5 mol. % to about 25 mol. %; and/or aromatic diol(s) (e.g., BP and/or HQ) in an amount of from about 2 mol. % to about 40 mol. %, and in some embodiments, from about 5 mol. % to about 35 mol. %.

B. Magnetic Particles

As indicated above, the polymer composition also contains magnetic particles that are distributed within the polymer matrix. To help achieve the desired properties, the particles generally exhibit a strong degree of electromagnetism. For example, the particles may exhibit a relative high remanence value (Br), which is characteristic of the overall strength of the magnetic field created by the particles. The remanence value may, for instance, range from about 500 to about 2,000 mT, in some embodiments from about 650 to about 1,500 mT, and in some embodiments, from about 750 to 1,000 mT, such as determined at a temperature of 23° C. in accordance with JIS C 2501:2019 (generally equivalent to ASTM A977/A977M-07 (2020)). The maximum energy product (BHₘₐₓ), which is the density of magnetic energy characterized by the product of the maximum value of magnetic flux density (B) and magnetic field strength (H), may also be high, such as from about 50 to about 250 kJ/m³, in some embodiments from about 70 to about 200 kJ/m³, and in some embodiments, from about 80 to about 140 kJ/m³, such as determined at a temperature of 23° C. in accordance with JIS C 2501:2019 (generally equivalent to ASTM A977/A977M-07 (2020)). In addition to exhibiting a strong degree of magnetic properties, the particles are also capable of maintaining such properties under a variety of conditions. For example, the particles may exhibit a high degree of intrinsic coercivity (H_{ci}), which is a property characteristic of the ability of the particles to resist becoming demagnetized. For example, the intrinsic coercivity may range from about 400 to about 3,000 kA/m, in some embodiments from about 700 to about 2,500 kA/m, such as determined at a temperature of 23° C. in accordance with JIS C 2501:2019 (generally equivalent to ASTM A977/A977M-07 (2020)). The Curie temperature (Tc), which is the temperature at which the material loses its magnetism, may also be high, such as from about 200° C. to about 400° C., in some embodiments from about 250° C. to about 350° C., and in some embodiments, from about 280° C. to about 320° C., such as determined by thermogravimetric analysis in accordance with ASTM E1582-17.

To help achieve a balance between magnetic strength and the mechanical and flow properties of the resulting polymer composition, the median (D50) particle size of the particles is generally selected within a controlled range, such as from 1 to about 200 micrometers, in some embodiments about 5 to about 150 micrometers, in some embodiments about 10 to about 120 micrometers, in some embodiments from about 25 to about 100 micrometers, and in some embodiments, from about 50 to about 90 micrometers, as determined by passing the particles through a mesh screen analysis (e.g., with 140 Mesh screen having 107×107 μm openings, 170 Mesh screen having 89×89 μm openings, and 325 Mesh screen having 45×45 μm openings). The particles may also have a relatively narrow size distribution such that at least 95 vol. % (D95) or 97 vol. % (D97) of the particles have a size within the ranges noted above.

The material used to form the magnetic particles may vary based on the desired properties. Nevertheless, the magnetic particles typically contain one or more rare earth elements, such as neodymium, praseodymium, lanthanum, cerium, samarium, yttrium, iron, cobalt, zirconium, niobium, titanium, chromium, vanadium, molybdenum, tungsten, hafnium, aluminum, manganese, copper, silicon, boron, or a combination thereof. Such rare earth particles may be formed by pulverizing an alloy for rare earth magnets to form alloy powder, compacting the alloy powder, and subjecting the alloy powder to sintering and aging. Particularly suitable rare earth materials for use in forming the magnetic particles are rare earth-iron-boron materials (hereinafter, referred to as “RFeB type magnets”, where R is any rare earth element, such as neodymium (Nd)). Generally speaking, such materials exhibit the highest magnetic energy product among a variety of magnets. In one particular embodiment, for example, the particles may be formed from a rare earth material having the following general formula:

(R₁₋ₐR′ₐ)ᵤFe_{100-u-v-w-x-y}ZᵥM_{w}TₓB_{y}

wherein,

R is Nd, Pr, Didymium (a nature mixture of Nd and Pr at composition of Nd_{0.75}Pr_{0.25}), MM or a combination thereof;

MM is a mischmetal or a synthetic equivalent thereof;

R′ is La, Ce, Y, or a combination thereof;

Z is a transition metal other than Fe, such as Co, Rh, Ir, Mt, Ni, Pd, Pt, Ds, or a combination thereof;

M is Zr, Nb, Ti, Cr, V, Mo, W, Rf, Ta, Db, Sg, Hf, or a combination thereof;

T is Al, Cu, Ag, Au, Zn, Cd, Hg, Ga, In, Ti, Ge, Sn, Pb, Si, or a combination thereof;

a is from 0 to 1, in some embodiments from 0.1 to 0.8, and in some embodiments, from 0.2 to 0.6;

u is from 7 to 13, in some embodiments from 10 to 13, and in some embodiments, from 11 to 12;

v is from 0 to 20, in some embodiments from 0 to 10, and in some embodiments, from 0 to 5;

w is from 0 to 5, in some embodiments from 0.1 to 1, and in some embodiments, from 0.2 to 0.8;

x is from 0 to 5, in some embodiments from 0.1 to 5, and in some embodiments, from 1 to 4.5; and

y is from 4 to 12, in some embodiments from 4 to 10, and in some embodiments, from 5 to 6.5.

In specific embodiments, R is Nd and/or Y is Co. M may likewise be Zr, Nb, or a combination thereof and/or T may be Al, Mn, or a combination thereof. The mischmetal or synthetic equivalent thereof (MM) may be a cerium-based mischmetal, such as a material containing 20% to 30% La, 2% to 8% Pr, 10% to 20% Nd, 40% to 55% Ce, and any incidental impurities.

If desired, the magnetic material particles may also contain an antioxidant, such as a phosphoric acid precursor (e.g., phosphate ion donor) as described in U.S. Patent Publication 2012/0119860, which is incorporated herein in its entirety by reference thereto. More particularly, the phosphate ions of the antioxidant can form a complex with the rare earth element. A source of phosphate ions may be phosphate-containing compounds such as a metal phosphate complex. The metal phosphate complex may be selected from the group consisting of lithium phosphate, sodium phosphate, potassium phosphate, magnesium phosphate, calcium phosphate and aluminum phosphate.

C. Pigment

Although not required, the polymer composition may optionally contain a pigment to help increase the optical density of the composition for certain types of applications, such as when the composition is employed in a magnetic sensor. The optical density is the absorbance of a material and can generally be determined by a logarithmic measurement of the percent transmission (% T) according to the equation, A (optical density)=log 10 100/% T. In certain embodiments, the optical density of the polymer composition may, for instance, be about 2 or more, in some embodiments about 3 or more, in some embodiments about 4 or more, and in some embodiments, from about 5 to about 20, for wavelengths ranging from 400 to 1,500 nanometers. The polymer composition may exhibit such optical density values at a variety of different part thicknesses, such as at a thickness of about 2 millimeters or less, in some embodiments from about 0.1 to about 1.5 millimeters, and in some embodiments, from about 0.2 to about 1 millimeter (e.g., about 0.5 millimeters).

A variety of pigments may generally be employed to help achieve such optical density values. For example, in some embodiments, the pigment may be a black pigment, such as particles, dyes, colorants, etc. When employed, the black particles may be formed from a carbon material, such as carbon black (e.g., furnace black, channel black, acetylene black, or lamp black). The carbon particles may have any desired shape, such as a granular, flake (scaly), etc. The average size (e.g., diameter) of the carbon particles may be relatively small, such as from about 1 to about 200 nanometers, in some embodiments from about 5 to about 150 nanometers, and in some embodiments, from about 10 to about 100 nanometers. It is also typically desired that the carbon particles are relatively pure, such as containing polynuclear aromatic hydrocarbons (e.g., benzo[a]pyrene, naphthalene, etc.) in an amount of about 1 part per million (“ppm”) or less, and in some embodiments, about 0.5 ppm or less. For example, the carbon particles may contain benzo[a]pyrene in an amount of about 10 parts per billion (“ppb”) or less, and in some embodiments, about 5 ppb or less. If desired, the particles may also have a high specific surface area, such as from about 20 square meters per gram (m²/g) to about 1,000 m²/g, in some embodiments from about 25 m²/g to about 500 m²/g, and in some embodiments, from about 30 m²/g to about 300 m²/g. Surface area may be determined by the physical gas adsorption (BET) method (nitrogen as the adsorption gas) in accordance with ASTM D6556-19a. Without intending to be limited by theory, it is believed that particles having such a small size, high purity, and/or high surface area may improve the adsorption capability for many free radicals, which can minimize oxidation of the liquid crystalline polymer.

If desired, the carbon material may include a carrier resin that can encapsulate the carbon particles, thereby providing a variety of benefits. For example, the carrier resin can enhance the ability of the particles to be handled and incorporated into the polymer matrix. While any known carrier resin may be employed for this purpose, in particular embodiments, the carrier resin may be a liquid crystalline polymer such as described above, which may be the same or different than the liquid crystalline polymer employed in the polymer matrix. If desired, the carrier resin may be pre-blended with the carbon particles to form a masterbatch, which can later be combined with the polymer matrix. When employed, the carrier resin typically constitutes from about 40 wt. % to about 90 wt. %, in some embodiments from about 50 wt. % to about 80 wt. %, and in some embodiments, from about 60 wt. % to about 70 wt. % of the masterbatch, and the carbon particles typically constitute from about 10 wt. % to about 60 wt. %, in some embodiments from about 20 wt. % to about 50 wt. %, and in some embodiments, from about 30 wt. % to about 40 wt. % of the masterbatch. The relative concentration of the carbon particles and the carrier resin may be selectively controlled in the present invention to achieve the desired optical properties without adversely impacting the magnetic, mechanical, and flow properties of the polymer composition. For example, the carbon particles are typically employed in an amount of from about from about 0.01 to about 8 wt. %, in some embodiments from about 0.05 to about 4 wt. %, and in some embodiments, from about 0.1 to about 2 wt. % of the entire polymer composition. The carbon material, which may contain a carrier resin, may likewise constitute from about 0.1 wt. % to about 15 wt. %, in some embodiments from about 0.2 wt. % to about 10 wt. %, and in some embodiments, from about 0.4 wt. % to about 5 wt. % of the polymer composition, as well as from about 0.5 vol. % to about 30 vol. %, in some embodiments from about 1 vol. % to about 15 vol. %, and in some embodiments, from about 2 vol. % to about 10 vol. % of the polymer composition.

D. Other Additives

If desired, a wide variety of additional additives can also be included in the polymer composition, such as lubricants, thermally conductive fillers, antioxidants, stabilizers, surfactants, waxes, flame retardants, anti-drip additives, nucleating agents (e.g., boron nitride) and other materials added to enhance properties and processability. Lubricants, for instance, may be employed in the polymer composition that are capable of withstanding the processing conditions of the liquid crystalline polymer without substantial decomposition. Examples of such lubricants include fatty acids esters, the salts thereof, esters, fatty acid amides, organic phosphate esters, and hydrocarbon waxes of the type commonly used as lubricants in the processing of engineering plastic materials, including mixtures thereof. Suitable fatty acids typically have a backbone carbon chain of from about 12 to about 60 carbon atoms, such as myristic acid, palmitic acid, stearic acid, arachic acid, montanic acid, octadecinic acid, parinric acid, and so forth. Suitable esters include fatty acid esters, fatty alcohol esters, wax esters, glycerol esters, glycol esters and complex esters. Fatty acid amides include fatty primary amides, fatty secondary amides, methylene and ethylene bisamides and alkanolamides such as, for example, palmitic acid amide, stearic acid amide, oleic acid amide, N,N′-ethylenebisstearamide and so forth. Also suitable are the metal salts of fatty acids such as calcium stearate, zinc stearate, magnesium stearate, and so forth; hydrocarbon waxes, including paraffin waxes, polyolefin and oxidized polyolefin waxes, and microcrystalline waxes. Particularly suitable lubricants are acids, salts, or amides of stearic acid, such as pentaerythritol tetrastearate, calcium stearate, or N,N′-ethylenebisstearamide. When employed, the lubricant(s) typically constitute from about 0.05 wt. % to about 1.5 wt. %, and in some embodiments, from about 0.1 wt. % to about 0.5 wt. % (by weight) of the polymer composition.

### II. Formation

The components of the polymer composition may be melt processed or blended together. The components may be supplied separately or in combination to an extruder that includes at least one screw rotatably mounted and received within a barrel (e.g., cylindrical barrel) and may define a feed section and a melting section located downstream from the feed section along the length of the screw. The extruder may be a single screw or twin screw extruder. The speed of the screw may be selected to achieve the desired residence time, shear rate, melt processing temperature, etc. For example, the screw speed may range from about 50 to about 800 revolutions per minute (“rpm”), in some embodiments from about 70 to about 150 rpm, and in some embodiments, from about 80 to about 120 rpm. The apparent shear rate during melt blending may also range from about 100 seconds⁻¹ to about 10,000 seconds⁻¹, in some embodiments from about 500 seconds⁻¹ to about 5000 seconds⁻¹, and in some embodiments, from about 800 seconds⁻¹ to about 1200 seconds⁻¹. The apparent shear rate is equal to 4Q/πR³, where Q is the volumetric flow rate (“m³/s”) of the polymer melt and R is the radius (“m”) of the capillary (e.g., extruder die) through which the melted polymer flows. The melt viscosity of the resulting polymer composition may be relatively low, which can not only enhance flowability during processing, but also can synergistically improve other properties of the composition. For example, the polymer composition may have a melt viscosity of about 200 Pa-s or less, in some embodiments from about 1 to about 100 Pa-s, in some embodiments from about 2 to about 80 Pa-s, in some embodiments from about 5 to about 60 Pa-s, and in some embodiments, from about 10 to about 40 Pa-s, as determined at a shear rate of 1,000 seconds⁻¹. Melt viscosity may be determined in accordance with ISO Test No. 11443:2014 at a temperature that is 15° C. higher than the melting temperature of the composition (e.g., about 395° C. for a melting temperature of about 380° C. or 350° C. for a melting temperature of 335° C.).

### III. Magnetic Component

As indicated above, the polymer composition of the present invention is particularly well suited for use in a magnetic component, such as a magnetic sensor, magnetic switch (e.g., switch that is combined with a magnetic sensor), clasp for an electrical component (e.g., wall charger), discrete magnet for use in an electrical component (e.g., speaker, camera module, receiver, voice coil motor, vibration motor, earbud, earphone, headset, etc.), housing, and so forth. Suitable magnetic sensors may include, for instance, Hall effect sensors, magnetoresistive sensors (e.g., anisotropic), magneto-optical sensors (MOsensors), etc. Hall effect sensors contain a magnetic sensing material that exhibits a change in Hall voltage when a magnetic field is applied across the sensor element, while magnetoresistive sensors contains a magnetic sensing material that exhibits a change in resistance when a magnetic field is applied across the sensor element. In contrast, MOsensors are based on the Faraday-effect instead of electrical effects to analyze magnetic fields. Various examples of such sensors are described, for instance, in U.S. Pat. Nos. 9,664,747; 10,914,567; and 10,955,494, as U.S. Patent Publication No. 2020/0319265, all of which are incorporated herein by reference. Regardless of the type, such components generally contain one or more layers of a magnetic sensing material, which may be formed from the polymer composition of the present invention.

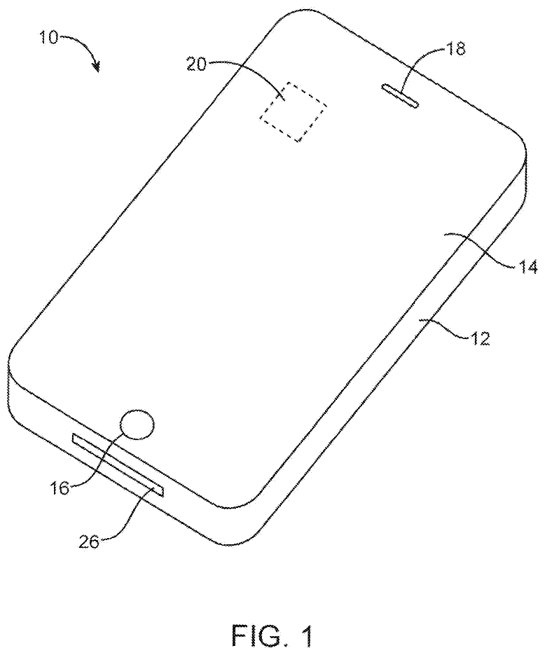

The magnetic component may be employed in a wide variety of electronic devices as is known in the art, such as in portable electronic devices (e.g., cellular telephones, portable computers, tablets, watches, etc.), computers, media players, televisions, automotive parts, Global Positioning Systems, cameras, gaming devices, etc. Referring to FIG. 1, for example, one embodiment of an electronic device 10 is shown that includes one or more magnetic sensors 20. As shown, the device 10 may have a housing 12, display 14, one or more buttons 16 that may be used to gather user input, one or more data ports 26, and additional input-output components (e.g., speaker 18). The device 10 may also be provided with one or more internal magnetically sensitive devices, such as a magnetic sensor 20, arranged in magnetically quiet regions of the electronic device and coupled to compass interface circuitry. Compass interface circuitry may be configured to combine magnetic field data from multiple sensors 20, generate directional compass data, and provide the compass data to other circuitry. Compass interface circuitry or other control circuitry in device 10 may be configured to store compass calibration data, may be configured to turn compass 30 on and off, may be configured to access information on the operational status of other electronic components, may be configured to apply corrections to compass data based on operational status information (also called status data, operational status data, etc.) associated with other electronic components, may be configured to combine these functions, or to perform any other compass related functions for device 10.

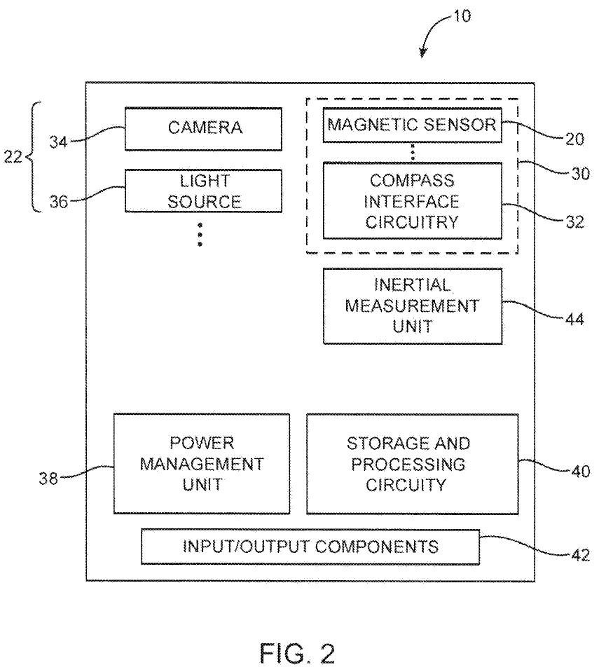

Referring to FIG. 2, for example, the magnetic sensors 20 may be combined with circuitry, such as compass interface circuitry 32, to form a compass 30. The compass interface circuitry 32 may be formed in part on magnetic sensors 20 and in part separately from magnetic sensors 20, or may be formed entirely separately from sensors 20. Regardless, the compass interface circuitry 32 may be configured to collect raw magnetic field data from sensors 20 and provide associated compass data to other control circuitry, such as storage and processing circuitry 40 of the device 10. Storage and processing circuitry 40 may be configured to deliver compass data from compass 30 to other software applications running on circuitry 40. As shown in FIG. 2, the device 10 may also include other electronic components 22, such as one or more cameras (e.g., a front-facing camera, a rear-facing camera, etc.), one or more light sources (e.g., a camera flash, an LED camera light, a flashlight, etc.) or other components that generate magnetic fields that may interfere with detection of the Earth's magnetic field. The magnetic sensors 20 may be positioned within the device 10 in relatively magnetically quiet regions of the device (e.g., away from components 22 or near a battery for the device).

In certain embodiments, the device 10 may also contain a positioning sensor, such as inertial measurement unit (IMU) 44. The inertial measurement unit 44 may include one or more accelerometers, one or more gyroscopes, GPS circuitry, etc. for determining the location and position of device 10. Storage and processing circuitry 40 may be configured to operate IMU 44 in combination with the compass 30 to provide position and location information to applications running on device 10. Storage and processing circuitry 40 may be used to operate power management unit (PMU) 38 to supply electrical power to components 22, such as camera 34 and light source 36. Storage and processing circuitry 40 may be used to operate input/output components such as input/output components 42 and to process and store data input to device 10 using input/output components 42. The input/output components 42 may include buttons or speakers, such as button 16 and speaker 18 of FIG. 1. Input/output components 42 may include touch-sensitive portions of display 14, may include a keyboard, wireless circuitry such as wireless local area network transceiver circuitry and cellular telephone network transceiver circuitry, and other components for receiving input and supplying output. Components 22 may be internal to device 10 or may have portions that are visible on a portion of an exterior surface of device 10. Any of the components noted above (e.g., speaker 18, input/output components 42, magnetic sensors 20, etc.) may contain the polymer composition of the present invention.

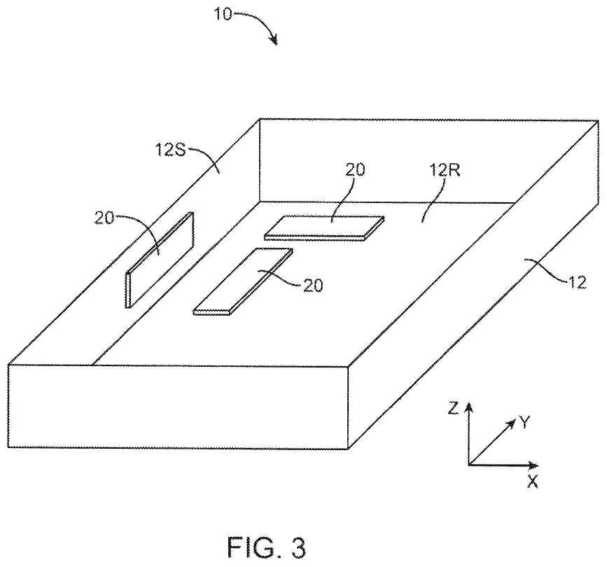

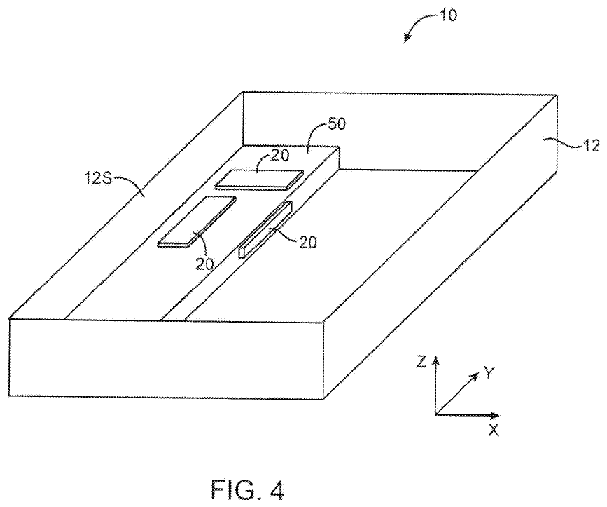

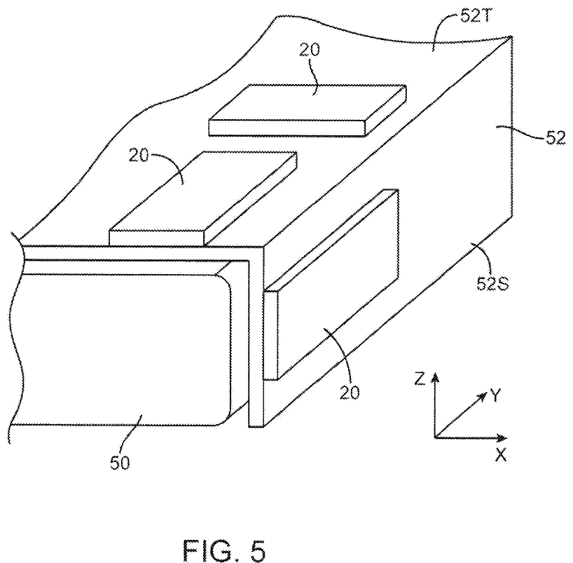

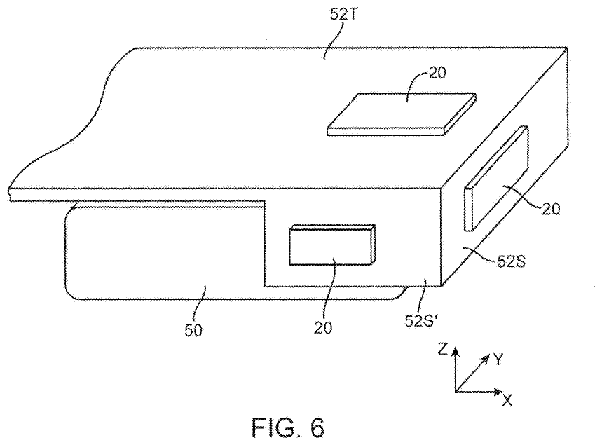

The magnetic sensors 20 may be incorporated within the device 10 in a variety of ways. As shown in FIG. 3, for example, the magnetic sensors 20 may be attached to portions of the housing 12. More particularly, in this example, the device 10 includes three unidirectional magnetic sensors 20 attached to housing sidewalls 12S and rear housing portion 12R. Each unidirectional magnetic sensor 20 may be aligned along a direction that is orthogonal to the other two sensors 20. For example, one sensor may have an elongated dimension that is aligned along the x-direction of FIG. 3, one sensor may have an elongated dimension that is aligned along the y-direction, and one sensor may have an elongated dimension that is aligned along the z-direction. In this way, the magnetic sensors, in combination, may be positioned so that they sample all orthogonal components of the Earth's magnetic field. However, this is merely illustrative. If desired, device 10 may include multi-directional magnetic sensors (e.g., sensors 20 with sensor elements configured to detect magnetic field components in two or three orthogonal directions). Magnetic field data gathered using three sensors 20 or multiple sensor elements on one or two sensors 20 may be combined (e.g., using compass interface circuitry 32) to form directional compass data that includes information associated with the direction in which device 10 is oriented with respect to the Earth's magnetic field. FIG. 4 shows another embodiment in which the sensors 20 are mounted to a component 50 within the device 10, such as a battery or other component in device 10 that generates relatively small magnetic fields (e.g., magnetic fields that minimally interfere with the detection of the Earth's magnetic field). The sensors 20 may also be mounted on other structures, such as a cover (cowling) structure. In FIG. 5, for instance, a cowling 52 may used to at least partially surround the component 50 (e.g., battery) and the sensors 20 may be mounted thereon. The cowling structure 52 may include a top portion 52T that covers an extended top surface of the component 50 and a side portion 52S that is orthogonal to the top portion 52T. The side portion 52S and top portion 52T may be formed from a common structure that has been folded or bent, or side portion 52S may be a separate structure that is attached to or mounted adjacent to top portion 52T. In the illustrated embodiment, two sensors 20 are mounted in orthogonal directions (e.g., parallel to the x and y directions of FIG. 5) on a top surface 52T and a third sensor 20 is attached to an orthogonal folded side portion 52S of structure 52. As shown in FIG. 6, the cowling structure 52 may also include an additional side portion 52S′ that is orthogonal to both sidewall portion 52 and top portion 52T. In this way, the structure 52 may be provided with three orthogonal surfaces on which three unidirectional magnetic sensors 20 may be mounted.

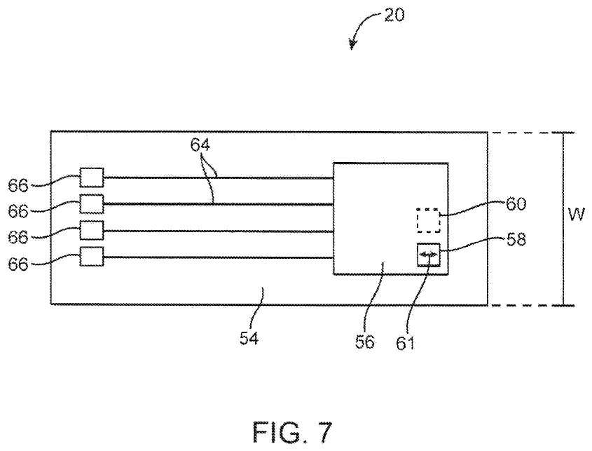

The manner in which the magnetic sensors 20 are formed may vary as is known to those skilled in the art. Referring to FIG. 7, for instance, one particular embodiment of such as sensor 20 is shown in more detail. More particularly, the sensor 20 has a width “w” and includes a magnetic sensing element 58, which contain the polymer composition of the present invention. The sensing element 58 may be disposed on a sensor circuitry substrate 56 (e.g., silicon) so that magnetic fields that are aligned along the direction indicated by arrows 61 generate a response in magnetic sensing element 58 that can be detected by circuitry in substrate 56 or other circuitry in device 10. In this way, the sensor 20 may be configured as a unidirectional magnetic sensor. The circuitry substrate 56 may be encapsulated by a protective substrate 54 (e.g., polyimide, epoxy resin, etc.) that includes conductive traces 64 and electrical contacts 66. The electrical contacts 66 may be attached to a printed circuit board, to another flexible printed circuit, or to other circuitry within device 10. The traces 64 may be used to route magnetic field data from the substrate 56 to other device circuitry, such as compass interface circuitry 32 (FIG. 2). To help detect and remove noise signals due to environmental changes, the sensor 20 may also be provided with a reference magnetic sensing element 60, which may contain the polymer composition of the present invention.

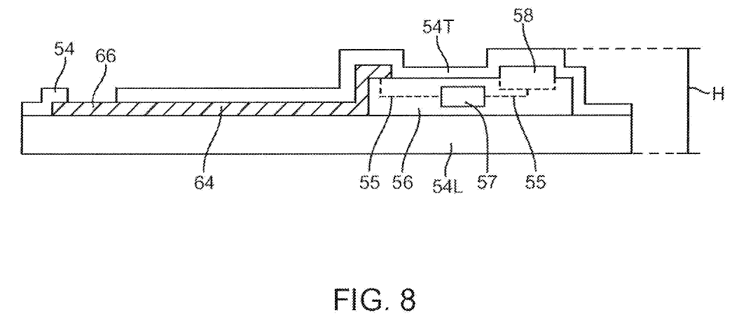

Referring to FIG. 8, the magnetic sensing element 58 may be formed on top of (or partially or completely embedded within) the protective substrate 54. The circuitry substrate 56 may be mounted on a bottom layer of substrate 54L and may be covered by additional substrate material 54T. Conductive traces 64 may be formed between top and bottom layers 54T and 54B of the protective substrate 54. Each conductive trace 64 may include an exposed portion that serves as a conductive contact 66. An opposing end of trace 64 may be coupled to conductive traces such as traces 55 in the circuitry substrate 56, thereby coupling magnetic sensing element 58 to contacts 66. Conductive traces 64 may be formed from a magnetically transparent material (e.g., copper) so that they do not interfere with magnetic fields in the vicinity of sensor 20. The circuitry substrate 56 may include circuitry 57 for processing magnetic field signals received from the magnetic sensing element 58. For example, in configurations in which the circuitry substrate 56 is provided with one or more magnetic sensing elements 58 and one or more reference sensing elements 60, the circuitry 57 may be used to modify magnetic field signals from element(s) 58 using magnetic field signals from element(s) 60 (e.g., by removing effects due to changes in the temperature of substrate 56 from magnetic field signals gathered by the element(s) 58).

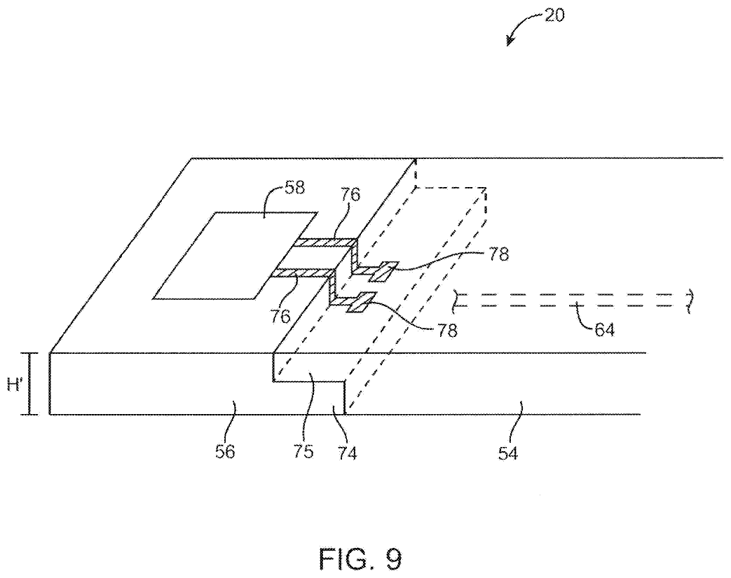

As depicted, the sensor 20 may be a relatively thin sensor having a characteristic maximum height “H” along a dimension that is perpendicular to a surface of sensor 20 and passes through substrate 56 and the magnetic sensing element 58. The height may, for example, be about 200 micrometers or less, and in some embodiments, from about 40 to about 150 micrometers. If desired, the height of the sensor 20 may be further reduced by providing the circuitry substrate 56 with a recessed portion for receiving printed circuit 54, such as shown in FIG. 9. In FIG. 9, for instance, a portion of the substrate 56 is removed so that an extended portion 74 of the substrate 56 can interface with an extended portion 75 of the protective substrate 54. In this way, the circuitry substrate 56 may be provided without any top layer of printed circuit material. In a configuration of the type shown in FIG. 9, the circuitry substrate 56 may be provided with conductive traces 76 that extend from magnetically sensitive magnetic sensing element 58 onto the extended portion 74 and connect to the electrical contacts 78. The electrical contacts 78 may be coupled to traces 64 in the protective substrate 54. By providing the substrate 54 and substrate 56 of with interfacing extended portions, the height of sensor 20 may be reduced to a height H′ that is about 150 micrometers or less, and in some embodiments, from about 30 to about 100 micrometers.

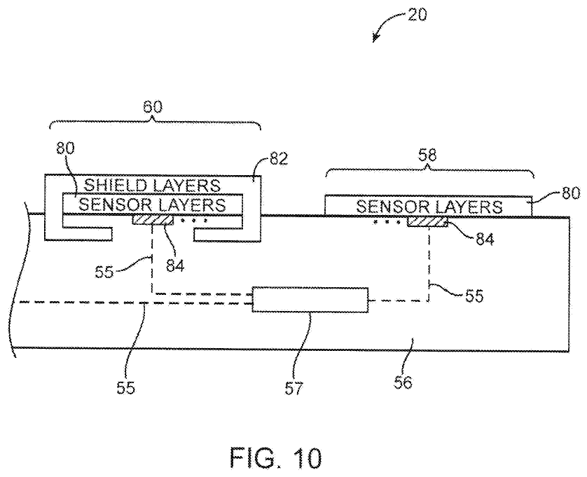

FIG. 10 shows a cross-sectional side view of the magnetic sensor in which the magnetic sensing element 58 and the reference sensing element 60 are formed on a common surface of the circuitry substrate 56. In this embodiment, the circuitry substrate 56 may include electrical contacts 84 (e.g., exposed portions of a conductive metal layer in substrate 56) that are coupled to elements 58 and 60 and circuitry 57. Conductive lines 55 may be used to provide magnetic field data from elements 58 and 60 to circuitry 57 and/or to conductive traces 64 of printed circuit 54. As shown, both the magnetic sensing element 58 and the reference sensing element 60 may include magnetic sensor layers 80, which may contain the polymer composition of the present invention. The magnetic sensor layer 80 may include a magnetically sensitive material, such as the polymer composition of the present invention, as well as one or more other optional layers, such as passivation layers, shielding layers, conductive layers, etc. The reference element 60 may include one or more additional shielding layers 82 that cover the magnetic sensor layers 80 and prevent external magnetic fields from reaching the sensor layer 80 in the reference sensor. Such magnetically shielding materials may include mu-metals, nickel, or other suitable magnetic field shielding materials or combinations of materials.

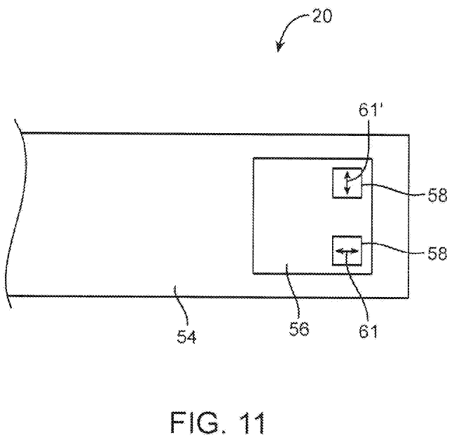

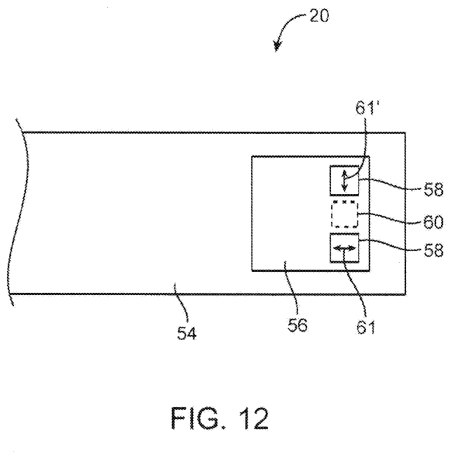

In the example of FIG. 10, the sensor 20 includes one magnetic sensing element 58 and one reference element 60. However, this is merely illustrative. If desired, sensor 20 may be provided without any reference sensors, or sensor 20 may be provided with more than one magnetic sensor element and/or more than one reference sensor element. Referring to FIG. 11, for example, the sensor 20 may be provided with two magnetic sensor elements. The sensor 20 may include a first sensor magnetic sensing element 58 that is configured to detect magnetic field components along a direction parallel to arrows 61 and a second sensor magnetic sensing element 58 that is configured to detect magnetic field components along an orthogonal direction that is parallel to arrows 61′. In this way, sensor 20 may be configured as bidirectional magnetic sensor (i.e., a sensor that can detect magnetic field components in two orthogonal directions). As shown in FIG. 12, a bidirectional magnetic sensor 20 may also include a shared reference element 60. In this regard, signals from a first sensor magnetic sensing element 58 and reference element 60 may be combined (e.g., subtracted) and digitized (e.g., using circuitry 57 in substrate 56 or other circuitry in device 10). Signals from a second sensor magnetic sensing element 58 and reference element 60 may be combined (e.g., subtracted) and digitized (e.g., using circuitry 57 in substrate 56 or other circuitry in device 10). If desired, combined signals from each sensor 58 and the shared reference element 60 may be digitized using a common, shared analog-to-digital converter circuit.

Regardless of the manner in which it is employed, the desired magnetic component(s) may be formed using a variety of different techniques. Suitable techniques may include, for instance, film extrusion, thermoforming, blow molding, injection molding, low-pressure injection molding, extrusion compression molding, gas injection molding, foam injection molding, low-pressure gas injection molding, low-pressure foam injection molding, gas extrusion compression molding, foam extrusion compression molding, extrusion molding, foam extrusion molding, compression molding, foam compression molding, gas compression molding, etc. For example, an injection molding system may be employed that includes a mold within which the polymer composition may be injected. The time inside the injector may be controlled and optimized so that polymer matrix is not pre-solidified. When the cycle time is reached and the barrel is full for discharge, a piston may be used to inject the composition to the mold cavity. Compression molding systems may also be employed. As with injection molding, the shaping of the polymer composition into the desired article also occurs within a mold. The composition may be placed into the compression mold using any known technique, such as by being picked up by an automated robot arm. The temperature of the mold may be maintained at or above the solidification temperature of the polymer matrix for a desired time period to allow for solidification. The molded product may then be solidified by bringing it to a temperature below that of the melting temperature. The resulting product may be de-molded. The cycle time for each molding process may be adjusted to suit the polymer matrix, to achieve sufficient bonding, and to enhance overall process productivity.

### Test Methods

Melt Viscosity: The melt viscosity (Pa-s) may be determined in accordance with ISO Test No. 11443:2014 at a shear rate of 1,000 s⁻¹ and temperature 15° C. above the melting temperature using a Dynisco LCR7001 capillary rheometer. The rheometer orifice (die) had a diameter of 1 mm, length of 20 mm, L/D ratio of 20.1, and an entrance angle of 180°. The diameter of the barrel was 9.55 mm+0.005 mm and the length of the rod was 233.4 mm.

Melting Temperature: The melting temperature (“Tm”) may be determined by differential scanning calorimetry (“DSC”) as is known in the art. The melting temperature is the differential scanning calorimetry (DSC) peak melt temperature as determined by ISO Test No. 11357-2:2020. Under the DSC procedure, samples were heated and cooled at 20° C. per minute as stated in ISO Standard 10350 using DSC measurements conducted on a TA Q2000 Instrument.

Deflection Temperature Under Load (“DTUL”): The deflection under load temperature may be determined in accordance with ISO Test No. 75-2:2013 (technically equivalent to ASTM D648-18). More particularly, a test strip sample having a length of 80 mm, thickness of 10 mm, and width of 4 mm may be subjected to an edgewise three-point bending test in which the specified load (maximum outer fibers stress) was 1.8 Megapascals. The specimen may be lowered into a silicone oil bath where the temperature is raised at 2° C. per minute until it deflects 0.25 mm (0.32 mm for ISO Test No. 75-2:2013).

Tensile Modulus, Tensile Stress, and Tensile Elongation: Tensile properties may be tested according to ISO Test No. 527:2019 (technically equivalent to ASTM D638-14). Modulus and strength measurements may be made on the same test strip sample having a length of 80 mm, thickness of 10 mm, and width of 4 mm. The testing temperature may be 23° C., and the testing speeds may be 1 or 5 mm/min.

Flexural Modulus, Flexural Stress, and Flexural Elongation: Flexural properties may be tested according to ISO Test No. 178:2019 (technically equivalent to ASTM D790-10). This test may be performed on a 64 mm support span. Tests may be run on the center portions of uncut ISO 3167 multi-purpose bars. The testing temperature may be 23° C. and the testing speed may be 2 mm/min.

### Example 1

A sample may be formed that contains the following components:

| | Density (g/cm³) | Wt. % | Vol. % |
|---|---|---|---|
| LCP 1 | 1.4 | 14.7 | 42.2 |
| Lubricant | 1.01 | 0.3 | 1.2 |
| Magnetic Powder 1 | 7.61 | 80 | 42.3 |
| Black LCP Masterbatch | 1.4 | 5 | 14.4 |
| (80 wt. % LCP 1, 20 wt. % | | | |
| carbon black) | | | |

LCP 1 has a melting temperature of about 340° C. and contains 60% HBA, 18% TA, 12% BP, 5% HNA, and 5% APAP. Magnetic Powder 1 is a NdFeB magnetic powder obtained from Magnequench under the name “MQP-AA4-15-7.”

### Example 2

A sample may be formed that contains the following components:

| | Density (g/cm³) | Wt. % | Vol. % |
|---|---|---|---|
| LCP 1 | 1.4 | 14.7 | 42.3 |
| Lubricant | 1.01 | 0.3 | 1.2 |
| Magnetic Powder 2 | 7.61 | 80 | 42.2 |
| Black LCP Masterbatch | 1.4 | 5 | 14.4 |
| (80 wt. % LCP 1, 20 wt. % | | | |
| carbon black) | | | |

Magnetic Powder 2 is a Nd—Fe—Co—B magnetic powder obtained from Magnequench under the name “MQP-B+, which has a remanence (Bᵣ) of about 900 mT, energy product (BHₘₐₓ) of about 130 kJ/m³, intrinsic coercivity (H_{ci}) of 716-836 kA/m, and Curie temperature (Ta) of 360° C.

### Example 3

A sample may be formed that contains the following components:

| | Density (g/cm³) | Wt.% | Vol.% |
|---|---|---|---|
| LCP 2 | 1.4 | 14.7 | 42.2 |
| Lubricant | 1.01 | 0.3 | 1.2 |
| Magnetic Powder 1 | 7.61 | 80 | 42.3 |
| Black LCP Masterbatch | 1.4 | 5 | 14.4 |
| (80 wt. % LCP 1,20 wt. % | | | |
| carbon black) | | | |

LCP 2 has a melting temperature of about 325° C. and contains about 43% HBA, 8% TA, 29% HQ, and 20% NDA.

### Example 4

A sample may be formed that contains the following components:

| | Density (g/cm³) | Wt. % | Vol. % |
|---|---|---|---|
| LCP 1 | 1.4 | 14.7 | 42.3 |
| Lubricant | 1.01 | 0.3 | 1.2 |
| Magnetic Powder 2 | 7.61 | 80 | 42.2 |
| Black LCP Masterbatch | 1.4 | 5 | 14.4 |
| (80 wt. % LCP 1, 20 wt. % | | | |
| carbon black) | | | |

### Example 5

A sample may be formed that contains the following components:

| | Density (g/cm³) | Wt. % | Vol. % |
|---|---|---|---|
| LCP 1 | 1.4 | 13.7 | 44.5 |
| Lubricant | 1.01 | 0.3 | 1.4 |
| Magnetic Powder 3 | 7.61 | 85 | 50.9 |
| Black LCP Masterbatch | 1.4 | 1.0 | 3.2 |
| (80 wt. % LCP 1, 20 wt. % | | | |
| carbon black) | | | |

Magnetic Powder 3 is a Nd—Fe—B magnetic powder having a remanence (Br) of about 850 mT, energy product (BHmax) of about 119 kJ/m³, and intrinsic coercivity (Hci) of about 987 kA/m. The median particle size (D50) is about 45 micrometers and the D97 particle size is about 192 micrometers.

The sample was tested for various magnetic and mechanical properties as described above. The results are set forth in the table below.

| Property | Value |
|---|---|
| Br (mT) | 421 |
| Hei (kA/m) | 982 |
| BHmax (kJ/m³) | 32.1 |
| Flexural Strength (MPa) | 88 |
| Unnotched Izod Impact Strength (kJ/m²) | 10 |
| Tensile Strength (MPa) | 53 |
| Tensile Elongation at Break (%) | 1.45 |

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A polymer composition comprising from about 20 vol. % to about 60 vol. % of a polymer matrix that includes a liquid crystalline polymer and from about 20 vol. % to about 60 vol. % of magnetic particles, wherein the ratio of the volume of the polymer matrix to the volume of the magnetic particles is from about 0.6 to about 1.5.

2. The polymer composition of claim 1, wherein the polymer matrix constitutes from about 8 wt. % to about 50 wt. % of the polymer composition and the magnetic particles constitute from about 50 wt. % to about 99 wt. % of the polymer composition.

3. The polymer composition of claim 1, wherein the polymer composition exhibits a melt viscosity of 200 Pa-s or less as determined at a shear rate of 1,000 seconds⁻¹ and at a temperature 15° C. higher than the melting temperature of the composition in accordance with ISO Test No. 11443:2014.

4. The polymer composition of claim 1, wherein the polymer composition has a melting temperature of about 280° C. or more and/or a deflection temperature under load of about 200° C. or more as determined in accordance with ISO Test No. 75-2:2013 at a specified load of 1.8 MPa.

5. The polymer composition of claim 1, wherein the liquid crystalline polymer containing repeating units derived from naphthenic hydroxycarboxylic and/or dicarboxylic acids in an amount of about 15 mol. % or less of the polymer.

6. The polymer composition of claim 5, wherein the liquid crystalline polymer contains repeating units derived from 4-hydroxybenzoic acid in an amount of from about 40 mol. % to about 80 mol. % of the polymer and contains repeating units derived from 6-hydroxy-2-naphtoic acid in amount of from about 0.5 mol. % to about 15 mol. % of the polymer.

7. The polymer composition of claim 1, wherein the liquid crystalline polymer containing repeating units derived from naphthenic hydroxycarboxylic and/or dicarboxylic acids in an amount of greater than about 15 mol. % of the polymer.

8. The polymer composition of claim 7, wherein the liquid crystalline polymer contains repeating units derived from 4-hydroxybenzoic acid in an amount of from about 20 mol. % to about 60 mol. % of the polymer and contains repeating units derived from 2,6-naphthalenedicarboxylic acid in amount of from about 16 mol. % to about 50 mol. % of the polymer.

9. The polymer composition of claim 1, wherein the magnetic particles exhibit a remanence value of from about 300 to about 2,000 mT, as determined at a temperature of 23° C. in accordance with JIS C 2501:2019.

10. The polymer composition of claim 1, wherein the magnetic particles exhibit a maximum energy product of from about 15 to about 200 kJ/m³, as determined at a temperature of 23° C. in accordance with JIS C 2501:2019.

11. The polymer composition of claim 1, wherein the magnetic particles exhibit an intrinsic coercivity of from about 400 to about 3,000 kA/m, as determined at a temperature of 23° C. in accordance with JIS C 2501:2019.

12. The polymer composition of claim 1, wherein the magnetic particles exhibit a Curie temperature of from about 200° C. to about 400° C., as determined by thermogravimetric analysis in accordance with ASTM E1582-17.

13. The polymer composition of claim 1, wherein the magnetic particles have a median particle size of from about 1 to about 200 micrometers.

14. The polymer composition of claim 1, wherein the magnetic particles contain a rare earth element.

15. The polymer composition of claim 14, wherein the rare earth element includes neodymium.

16. The polymer composition of claim 1, wherein the magnetic particles contain a rare earth material having the following general formula:
(R₁₋ₐR′ₐ)ᵤFe_{100-u-v-w-x-y}ZᵥM_{w}TₓB_{y}
wherein,
R is Nd, Pr, Didymium, MM or a combination thereof;
MM is a mischmetal or a synthetic equivalent thereof;
R′ is La, Ce, Y, or a combination thereof;
Z is a transition metal other than Fe, such as Co, Rh, Ir, Mt, Ni, Pd, Pt, Ds, or a combination thereof;
M is Zr, Nb, Ti, Cr, V, Mo, W, Rf, Ta, Db, Sg, Hf, or a combination thereof;
T is Al, Cu, Ag, Au, Zn, Cd, Hg, Ga, In, Ti, Ge, Sn, Pb, Si, or a combination thereof;
a is from 0 to 1;
u is from 7 to 13;
v is from 0 to 20;
w is from 0 to 5;
x is from 0 to 5; and
y is from 4 to 12.

17. The polymer composition of claim 16, wherein a is from 0.1 to 0.8.

18. The polymer composition of claim 16, wherein R is Nd and Y is Co.

19. The polymer composition of claim 18, wherein M is Zr, Nb, or a combination thereof and T is Al, Mn, or a combination thereof.

20. The polymer composition of claim 1, further comprising carbon particles.

21. The polymer composition of claim 20, wherein the carbon particles include carbon black.

22. The polymer composition of claim 1, wherein the composition exhibits an optical density of about 4 or more, as determined at a thickness of about 0.5 millimeters and at a wavelength of from 400 to 1,500 nanometers.

23. A magnetic component comprising a magnetic sensing material, wherein the magnetic sensing material comprises the polymer composition of claim 1.

24. The magnetic component of claim 23, wherein the magnetic component includes a magnetic sensor.

25. An electronic device comprising the magnetic component of claim 24.

26. The electronic device of claim 25, wherein the device is a portable electronic device.
